(19) United States
(12) Patent Application Publication
(10) Pub. No.: US 2010/0140648 A1
(43) Pub. Date: Jun. 10, 2010

(54) SEMICONDUCTOR LIGHT EMITTING DEVICE AND METHOD FOR PRODUCING THE SAME

(76) Inventors: Mitsunori Harada, Tokyo (JP); Kaori Tachibana, Tokyo (JP); Masahiro Sanmyo, Tokyo (JP); Mika Mochizuki, Tokyo (JP); Masanori Sato, Tokyo (JP)

Correspondence Address: CERMAK KENEALY VAIDYA & NAKAJIMA LLP, 515 EAST BRADDOCK RD SUITE B, Alexandria, VA, 22314, US

(21) Appl. No.: 12/634,229

(22) Filed: Dec. 9, 2009

(30) Foreign Application Priority Data
Dec. 9, 2008 (JP) 2008-313084

(51) Int. Cl. H01L 33/00; H01L 21/66

(52) U.S. Cl. 257/98; 438/15; 257/E33.059; 257/E21.529

(57) ABSTRACT

A semiconductor light emitting device can be configured to maintain high luminance and to suppress the possibility of the occurrence of wire breakage with high quality and reliability. A method for producing such a semiconductor light emitting device with a high process yield is also disclosed. The semiconductor light emitting device can include a sealing member into which a reflective filler can be mixed in such an amount (concentration) range that luminous flux with a predetermined amount can be maintained and the possibility of the occurrence of wire breakage can be lowered. Various sealing members containing a reflective filler with a plurality of concentrations within this range can be prepared in advance. By taking advantage of the phenomenon where chromaticity shifts depending on the concentration of the reflective filler, a semiconductor light emitting device with less chromaticity variation can be produced utilizing a sealing member with a particular concentration in accordance with the chromaticity of a particular semiconductor light emitting element that is used and which may be varied during fabrication.

This application claims the priority benefit under 35 U.S.C. §119 of Japanese Patent Application No. 2008-313084 filed on Dec. 9, 2008, which is hereby incorporated in its entirety by reference.

### TECHNICAL FIELD

The presently disclosed subject matter relates to a semiconductor light emitting device and a method for producing the same. In particular, the presently disclosed subject matter relates to a semiconductor light emitting device that is produced by resin-sealing a semiconductor light emitting element, and to a method for producing the same.

### BACKGROUND ART

A known surface-mount semiconductor light emitting device can have a semiconductor light emitting element mounted on a submount substrate and bonding wires and the like that can be sealed with a resin-made sealing member (for example, see Japanese Patent Application Laid-Open No. 2005-026401A1). In the technique disclosed in JP 2005-026401A1 publication, it is proposed that the sealing member can function as a reflecting layer in order to prevent luminance deterioration. Specifically, such a sealing member can include a resin and a filler that is a white filler such as titanium oxide (TiO₂) so that the sealing member can reflect light that is emitted from the semiconductor light emitting element and that is directed to the sealing member to effectively utilize the emitted light.

### SUMMARY

In order to improve the reflectance by the sealing member and maintain the luminance of the device, it would be better to increase the amount of titanium oxide contained in the sealing member. However, the greater the amount of titanium oxide contained in the sealing member, the higher the hardness of the sealing member is. As a result, the internal stress accumulated therein due to environmental variation such as temperature variation may be increased, thereby affecting the bonding wires. Accordingly, when the amount of titanium oxide contained in the sealing member is increased in order to improve the reflectance, there is an increased possibility that the wire is broken due to accumulated stress.

The presently disclosed subject matter was devised in view of these and other problems, characteristics and features in association with the conventional art. According to an aspect of the presently disclosed subject matter, a semiconductor light emitting device can maintain its high luminance while suppressing the occurrence of wire breakage with high quality and high reliability. According to another aspect of the presently disclosed subject matter, a method for producing a semiconductor light emitting device can improve the yield of the produced semiconductor light emitting device.

According to still another aspect of the presently disclosed subject matter, a semiconductor light emitting device can include a sealing member into which a reflective filler can be mixed in such an amount (concentration) range that a predetermined amount of luminance (luminous flux) can be maintained and the possibility of the occurrence of wire breakage can be lowered. Various sealing members containing a reflective filler with a plurality of concentrations within this range are prepared in advance, and by taking advantage of the phenomenon where the chromaticity can be shifted depending on the concentration of the reflective filler, a semiconductor light emitting device with less chromaticity variation can be produced utilizing any of the sealing members with a particular concentration in accordance with the chromaticity of a used semiconductor light emitting element which may be varied during its fabrication.

Specifically, according to still another aspect of the presently disclosed subject matter, a semiconductor light emitting device can include: a semiconductor light emitting element; a wavelength conversion layer that contains a wavelength conversion material in a predetermined concentration, the wavelength conversion layer wavelength converting light emitted from the semiconductor light emitting element by exciting the wavelength conversion material with a part of the light; a substrate on which the semiconductor light emitting element and the wavelength conversion layer are disposed; a bonding wire for electrically connecting the semiconductor light emitting element to the substrate; a sealing member including a light transmitting resin and titanium dioxide as main ingredients, the sealing member being disposed on a side face of the wavelength conversion layer, the sealing member including titanium oxide in an amount of 0.1 to 8.0 wt %.

According to still another aspect of the presently disclosed subject matter, a method for producing a semiconductor light emitting device can include providing a semiconductor light emitting device including: a semiconductor light emitting element; a wavelength conversion layer that contains a wavelength conversion material in a predetermined concentration, the wavelength conversion layer wavelength converting light emitted from the semiconductor light emitting element by exciting the wavelength conversion material with a part of the light; a substrate on which the semiconductor light emitting element and the wavelength conversion layer are disposed; a bonding wire for electrically connecting the semiconductor light emitting element to the substrate; and a sealing member including a light transmitting resin and titanium oxide as main ingredients. The production method can include: measuring the chromaticity of the semiconductor light emitting element provided with the wavelength conversion layer; determining a concentration of titanium oxide to be contained in the sealing member based on a chromaticity shift amount being a difference between the measured chromaticity and a target chromaticity; and filling the device with the sealing member including the titanium oxide in the determined concentration of titanium oxide.

According to another aspect of the disclosed subject matter, a semiconductor light emitting device having a light emitting axis about which light is emitted in a light emitting direction when power is provided to the semiconductor light emitting device can include a semiconductor light emitting element, a wavelength conversion layer including a wavelength conversion material in a predetermined concentration, the wavelength conversion layer configured to wavelength convert light emitted from the semiconductor light emitting element, the wavelength conversion layer having a front face and a side face configured at an angle with respect to the front face, the light emitting axis intersecting the front face and completely spaced from the side face, a substrate located adjacent the semiconductor light emitting element and the wavelength conversion layer, a bonding wire electrically connected with the semiconductor light emitting element, and a sealing member including a light transmitting resin and a light dispersing material, the sealing member being in contact with the side face of the wavelength conversion layer to form a contact surface, an entire extent of the contact surface being spaced from the light emitting axis.

According to certain aspects of the presently disclosed subject matter, the semiconductor light emitting device can maintain the high luminance (luminous flux) while suppressing the occurrence of wire breakage with high quality and high reliability. According to another aspect of the presently disclosed subject matter, a method for producing a semiconductor light emitting device can improve the yield of the produced semiconductor light emitting device.

### BRIEF DESCRIPTION OF DRAWINGS

These and other characteristics, features, and advantages of the presently disclosed subject matter will become clear from the following description with reference to the accompanying drawings, wherein:

FIG. 1 is a cross-sectional view illustrating a semiconductor light emitting device made in accordance with principles of the presently disclosed subject matter;

FIG. 2 is a flow chart showing an exemplary method for producing the semiconductor light emitting device made in accordance with principles of the presently disclosed subject matter;

FIG. 3 is a diagram illustrating the light emission from the semiconductor light emitting device of FIG. 1;

FIG. 4 is a graph showing diffuse reflectance distribution based on a glass coated sample;

FIG. 5 is a graph showing a distribution of lumen maintenance ratios for the semiconductor light emitting device of FIG. 1;

FIG. 6 is a graph showing heat-shock test results for the semiconductor light emitting device of FIG. 1;

FIGS. 7A to 7C are sectional views illustrating modified examples of the semiconductor light emitting device of FIG. 1;

FIG. 8 is a graph showing the chromaticity shift amount distribution for another exemplary embodiment of a semiconductor light emitting device made in accordance with the principles of the presently disclosed subject matter; and

FIG. 9 is a flow chart showing an exemplary method for producing the semiconductor light emitting device of FIG. 8.

### DESCRIPTION OF EXEMPLARY EMBODIMENTS

A description will now be made below to semiconductor light emitting devices of the presently disclosed subject matter with reference to the accompanying drawings in accordance with exemplary embodiments.

### First Exemplary Embodiment

A first exemplary embodiment will be described with reference to the accompanying drawings. The same or similar components in the drawings illustrating the embodiments of the presently disclosed subject matter are denoted by the same reference numerals, and repetitive descriptions therefore will be appropriately omitted.

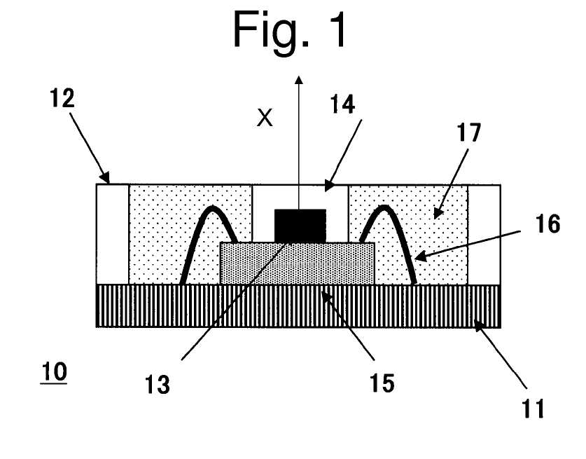

FIG. 1 is a cross-sectional view illustrating a semiconductor light emitting device made in accordance with the principles of the presently disclosed subject matter. As shown, the semiconductor light emitting device 10 of the presently disclosed subject matter can include: a substrate 11, a protective frame 12 disposed on the substrate 11, a semiconductor light emitting element (for example, a light emitting diode) 13, a wavelength conversion layer 14 formed so as to surround the semiconductor light emitting element 13, a submount 15 where the semiconductor light emitting element 13 and the wavelength conversion layer 14 are mounted, bonding wires (for example, gold (Au) wires) 16 configured to electrically connect the submount 15 and the substrate 11, and a sealing member 17 to be filled within the protective frame 12. The semiconductor light emitting device 10 can have a light emitting axis X about which light is directed when power is supplied to the semiconductor light emitting device 10. Light can be uniformly dispersed about the light emitting axis X when a standard light emitting element and no shading is provided. Alternatively, light can be non-uniformly dispersed about the light emitting axis X when either a non-uniformly shaped light emitting element or a non-uniformly shaped shade is provided. The light emitting direction of the light emitting device 10 extends upward and along the light emitting axis X as shown in FIG. 1.

The substrate 11 can be formed of a material with a high heat dissipation property. On the surface of the substrate 11, an electrode pattern (not shown) can be formed in advance. Examples of the material for the substrate 11 can include ceramics, silicon, glass epoxy, and the like.

The protective frame 12 can be formed on the substrate 11 and have an upper surface so that it is flush with the upper surface of the wavelength conversion layer 14. Examples of the material for forming the protective frame 12 can include ceramics, polyphthalamide (PPA) resins, silicon, glass, a kovar alloy, and the like.

The semiconductor light emitting element 13 can be formed by depositing light emitting layers on a transparent sapphire substrate and a high reflectance electrode formed on a surface of the light emitting layers. The semiconductor light emitting element 13 can be connected with the submount 15 in a flip-chip manner with an Au bump (not shown) so that the high reflectance electrode of the element faces to the submount 15. The light emitted from the light emitting layers can be taken out through the transparent sapphire substrate.

The wavelength conversion layer 14 can include a light transmitting resin such as a thermosetting silicone resin, an epoxy resin, or the like, and a fine-grain wavelength conversion material (such as a phosphor) that is dispersed in the light transmitting resin in a predetermined concentration. In the wavelength conversion layer 14, a part of light emitted from the semiconductor light emitting element 13 (serving as excitation light) can be wavelength converted by the phosphor or the like wavelength conversion material. The wavelength converted light can be mixed with another part of the light emitted from the semiconductor light emitting element 13 and which passes through the wavelength conversion layer 14 without wavelength conversion so that the mixed light can be emitted from the upper surface of the wavelength conversion layer 14. For example, a phosphor material can be selected that is excitable by blue light from a semiconductor light emitting element 13 and which emits yellow light as wavelength converted light. This configuration can allow the semiconductor light emitting device 10 to emit white light resulting from the mixture of the direct blue light and the wavelength converted yellow light.

Examples of the material for the submount 15 can include aluminum nitride, silicon, and the like. The semiconductor light emitting element 13 can be connected to the submount 15 in a flip-chip manner via an Au bump. The submount 15 can be connected to the substrate 11 by means of the Au wires 16 so that the semiconductor light emitting element 13 can be electrically connected to the substrate 11. In one mode, the Au wires 16 can be disposed inside the sealing member 17 as shown in FIG. 1. This is because, when the Au wires 16 are disposed across both the sealing member 17 and the wavelength conversion layer 14, the thin Au wires 16 may be adversely affected by both the layers having different thermal expansion coefficients and may possibly be broken. In addition to this, when the Au wires are disposed inside the wavelength conversion layer 14, the Au wires 16 can reflect light, resulting in the generation of glare light. Accordingly, it is sometimes beneficial for the Au wires 16 to be disposed inside the sealing member 17 because the generation of glare light can be suppressed.

The sealing member 17 of the present exemplary embodiment can be filled inside the protective frame 12 so that it can cover the entire side face of the wavelength conversion layer 14. The sealing member 17 can include a main ingredient of a resin material such as a silicone resin serving as a binder, in which a reflective material filler such as titanium oxide (TiO₂) can be mixed and dispersed in a predetermined concentration. In the present exemplary embodiment, the reflective material is designed to be mixed and dispersed in the resin material by an amount of less than 10 wt % as described later. Accordingly, the direct light emitted from the semiconductor light emitting element 13 and/or the wavelength converted light can reach the resin portion (binder) of the sealing member 17 where the reflective material does not exist. In view of this, the resin material (binder) for the sealing member should preferably be transparent to light (not completely absorb both the direct light and the wavelength converted light).

The reflective filler or titanium oxide (TiO₂) can be contained in an amount of 0.1 to 8.0 wt % (concentration), alternatively, around 1 wt %, and alternatively 0.5 to 2.0 wt %. The reflective filler contained in this range can provide a favorable reflectance as the sealing member 17 itself and maintain more appropriate luminance (luminous flux). Furthermore, since the binder resin can contain the filler in an appropriate concentration, the hardened sealing member 17 can have an appropriate elasticity modulus. This means internal stresses generated within the sealing member 17 due to the environmental temperature variation when used can be absorbed by the sealing member 17, thereby preventing the Au wires from being broken or the like.

An average particle diameter D (hereinafter, referred to as “particle diameter”) of primary particles of titanium oxide (TiO₂) to be mixed may be equal to 1 μm or less. In general, it is known that titanium oxide (TiO₂) with its particle diameter D of 1 μm or less can provide certain reflective (scattering) effect. This is because, when the particle diameter D is more than 1 μm, titanium oxide can settle and separate in the binder, whereas Rayleigh scattering can occur to decrease the opacifying power and increase the transparency when the particle diameter D is remarkably small as compared to the light wavelength λ. Further, it is known that the scattering effect is maximum around the half of light wavelength λ. In view of this, since the wavelength λ in the case of visible light is 0.4 to 0.8 μm (400 to 800 nm), the particle diameter D may be 0.2 to 0.4 μm.

Exemplary shapes of titanium oxide can include spherical, needle, and flake shapes.

Examples of the reflective filler other than titanium oxide can include a material having a refractive index outside the range of the refractive indices (for example, n=1.4 to 1.5) of resins serving as a binder resin. The material may be aluminum oxide (refractive index of n=1.56), magnesium oxide (refractive index of n=1.74), barium sulfate (refractive index of n=1.65), or the like. It should be noted that the refractive index of titanium oxide (TiO₂) is 2.76.

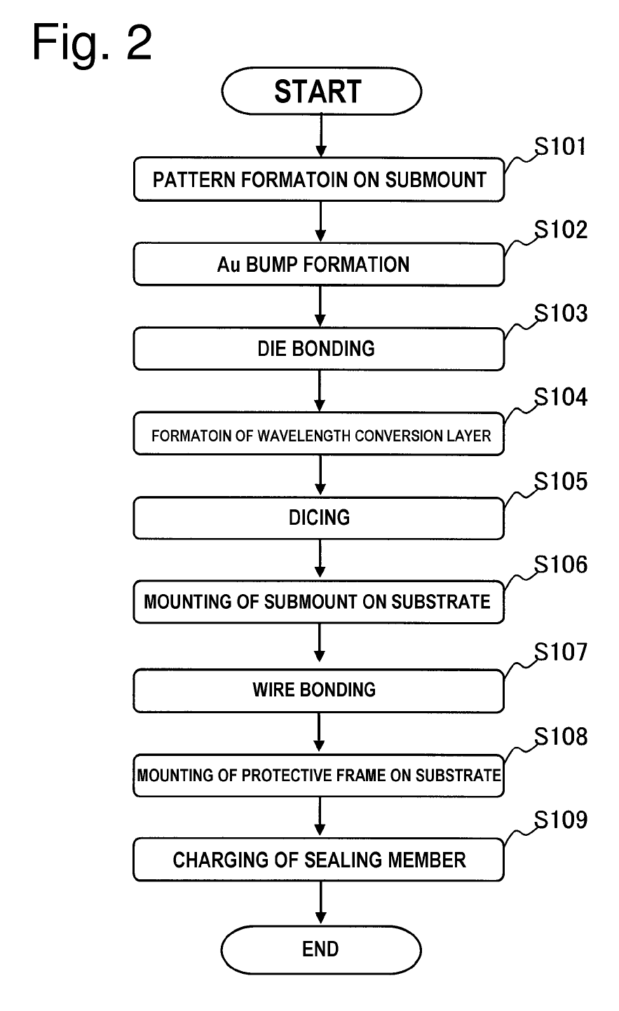

A description will now be given of one exemplary method for producing the semiconductor light emitting device 10 of the present exemplary embodiment. FIG. 2 is a flow chart showing the method for producing the semiconductor light emitting device.

First, a wiring pattern is formed on an upper surface of the submount 15 (process S101). Then, Au bumps are formed on surfaces of light emitting layers of the respective semiconductor light emitting elements 13 (process S102), and die-bonded (process S103). The Au bumps will serve as high reflectance electrodes. This achieves the flip-chip connection for the respective semiconductor light emitting elements 13 to the submount 15. Then, a mixture of materials constituting the wavelength conversion layer 14 can be applied to the respective semiconductor light emitting elements 13 so as to surround the elements 13 by using a dispenser coating method, screen printing method or stencil printing method. The wavelength conversion layer 14 can be heated to be hardened (process S104). Then the individual semiconductor light emitting elements 13 on the submount 15 can be separated by dicing or other mechanical cutting (process S105), or even other types of cutting.

Next, a heat conductive adhesive can be applied to the substrate 11 and the submount 15 can be disposed thereon (process S106). Then, the heat conductive adhesive can be cured, and the substrate 11 and the submount 15 can be wire-bonded with the bonding wires 16 (process S107). Next, an adhesive for fixing the protective frame 12 can be applied on the substrate 11, and the protective frame 12 can be disposed on a predetermined area of the substrate 11 (process S108). Then, the adhesive can be cured. The sealing member 17 can then be charged inside the protective frame 12 so that the upper surface of the sealing member 17 becomes flush with the upper surface of the wavelength conversion layer 14 (process S109). This can seal the wavelength conversion layer 14 covering the semiconductor light emitting element 13, the submount 15 and the bonding wires 16 with the sealing member 17.

In the exemplary semiconductor light emitting device 10 produced as described above and having the above-mentioned structure, the upper surface of the wavelength conversion layer 14 is exposed when viewed from its top. The upper surface of the layer 14 is not covered with the sealing member 17, and accordingly, the light projected from the upper surface of the wavelength conversion layer 14 does not pass through the sealing member 17. This can increase the resulting luminance when compared with the case where the upper surface thereof is covered with another member.

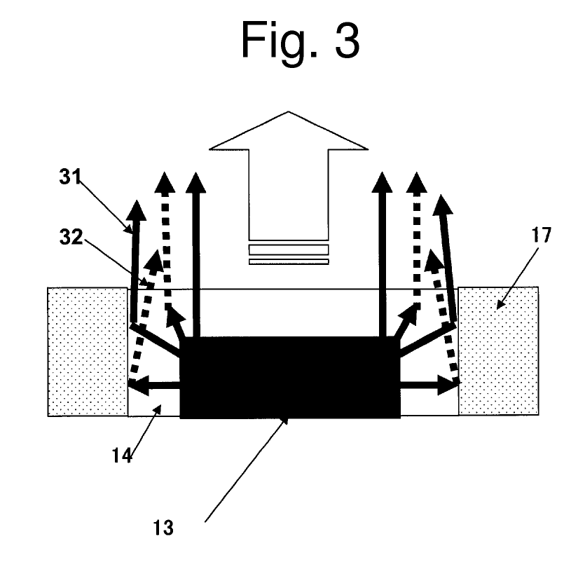

Further, in the exemplary semiconductor light emitting device 10, the sealing member 17 containing the mixed titanium oxide (TiO₂) is disposed so as to cover the side face of the wavelength conversion layer 14. The sealing member 17 can reflect light, and accordingly, almost all the light emitted from the side faces of the semiconductor light emitting element 13 can be directed upward. Specifically, as shown in FIG. 3, the light (including the excitation light) emitted from the side faces of the semiconductor light emitting element 13 can be reflected from the interface with the sealing member 17 to be returned into the wavelength conversion layer 14. A part of the returned light can be directly projected upward through the wavelength conversion layer 14 (denoted by reference numeral 31 in FIG. 3). The remaining part of light can excite the phosphor being a wavelength conversion material to become wavelength converted light, and then be scattered inside the wavelength conversion layer 14 and be directed upward (denoted by reference numeral 32 in FIG. 3). According to the semiconductor light emitting device 10 of the present exemplary embodiment, almost all the light emitted from the side faces of the semiconductor light emitting element 13 can be directed upward, resulting in a decrease in light loss.

Furthermore, in the semiconductor light emitting device 10 of the present exemplary embodiment, the titanium oxide concentration in the sealing member 17 is set within the range of 0.1 to 8 wt %. This means parts of the direct light emitted from the side faces of the semiconductor light emitting element 13 and the wavelength converted light can enter the light transmitting resin serving as the main component in the sealing member 17. Accordingly, the transmission/scattering ratio can be increased when compared with the case where the titanium oxide concentration is higher. In addition to this, the hardness of the sealing member 17 can be suppressed, resulting in lower accumulated stresses in the sealing member 17, which would be loaded onto the bonding wires 16, due to environmental variation such as temperature variation. Accordingly, a semiconductor light emitting device with high quality and reliability that can maintain its high luminance and prevent the breakage of bonding wires can be provided.

Variations in the diffuse reflectance and the total luminous flux maintenance ratio and the occurrence of the breakage of bonding wires were confirmed when the titanium oxide concentration (wt %) in the sealing member was changed. The total lumen maintenance ratio is the amount of luminous flux with respect to that before sealing normalized as 1.

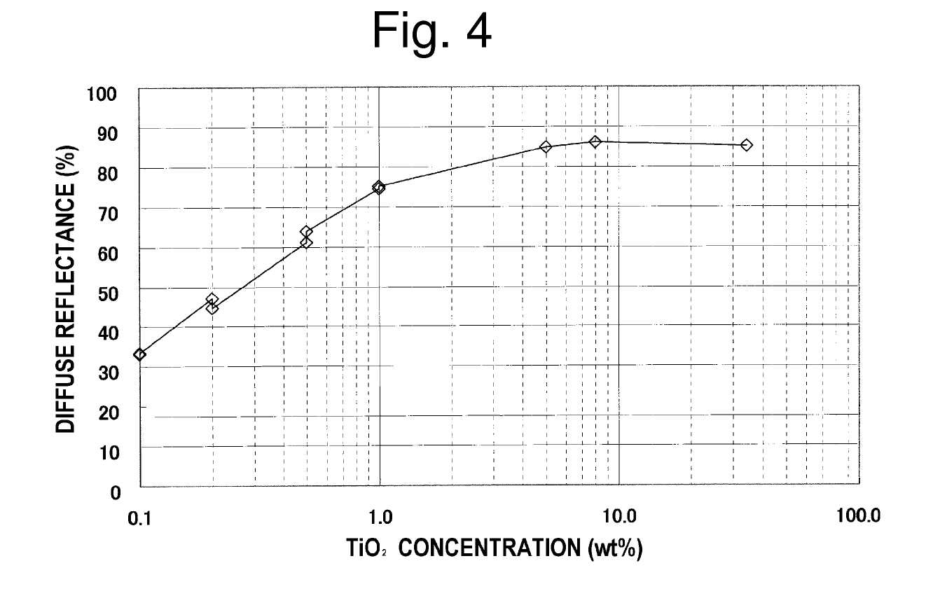

FIG. 4 is a graph showing the diffuse reflectance distribution when the titanium oxide concentration (wt %) in the sealing member is varied. In the graph, the horizontal axis shows the titanium oxide concentration (wt %) in the sealing member in logarithm, and the longitudinal axis shows the diffuse reflectance (%). Using coated glass samples with a thickness of 0.6 mm, the diffuse reflectances (%) thereof were measured while the titanium oxide concentration was varied in the range of 0.1 to 35 wt %. The titanium oxide that was used had a spherical shape with the average primary particle diameter of 1 μm or less. As shown in the drawing, if the titanium oxide concentration in the sealing member 17 is in the range of 8 wt % to 35 wt %, the test results show that the diffuse reflectance was not remarkably changed.

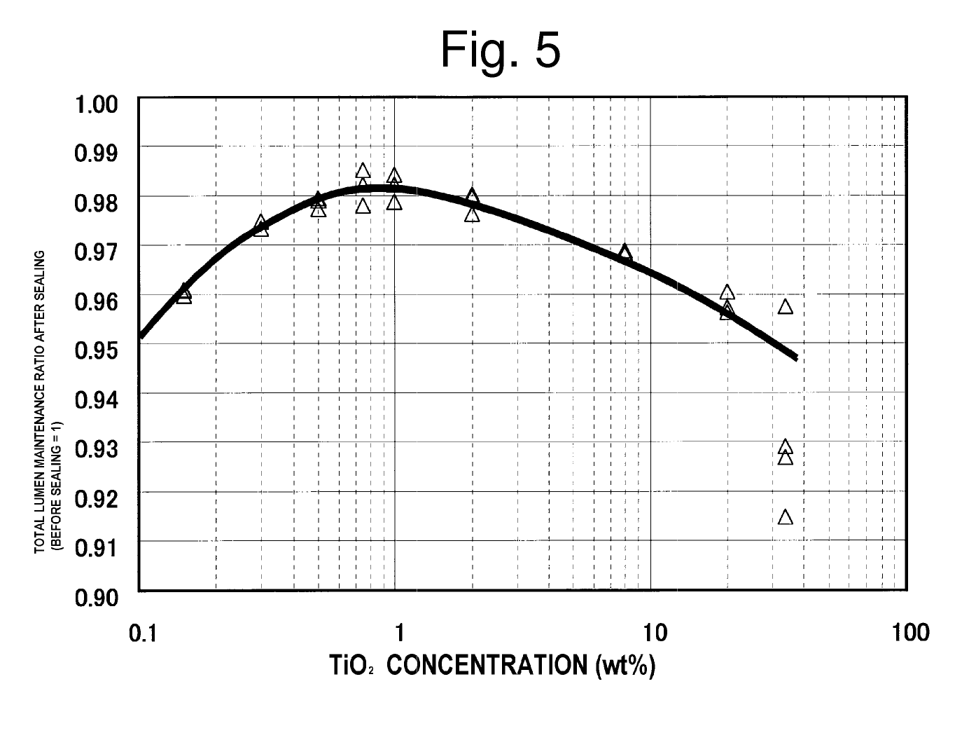

FIG. 5 is a graph showing the total lumen maintenance ratio distribution when the titanium oxide concentration (wt %) in the sealing member is varied. Using the semiconductor light emitting device 10 of the present exemplary embodiment, the titanium oxide concentration was varied in the range of 0.15 to 34 wt %. The titanium oxide that was used had a spherical shape with the average primary particle diameter of 1 μm or less. In the graph, the horizontal axis shows the titanium oxide concentration (wt %) in the sealing member in logarithm, and the longitudinal axis shows the total lumen maintenance ratio. As shown in the drawing, when the titanium oxide concentration in the sealing member 17 is in the range of 0.1 wt % to 35 wt %, the total lumen maintenance ratio is approximately 0.95. When the titanium oxide concentration in the sealing member 17 is in the range of 0.2 wt % to 8 wt %, the total lumen maintenance ratio is approximately 0.965. When the titanium oxide concentration in the sealing member 17 is in the range of 0.5 wt % to 2.0 wt %, the total lumen maintenance ratio is approximately 0.98.

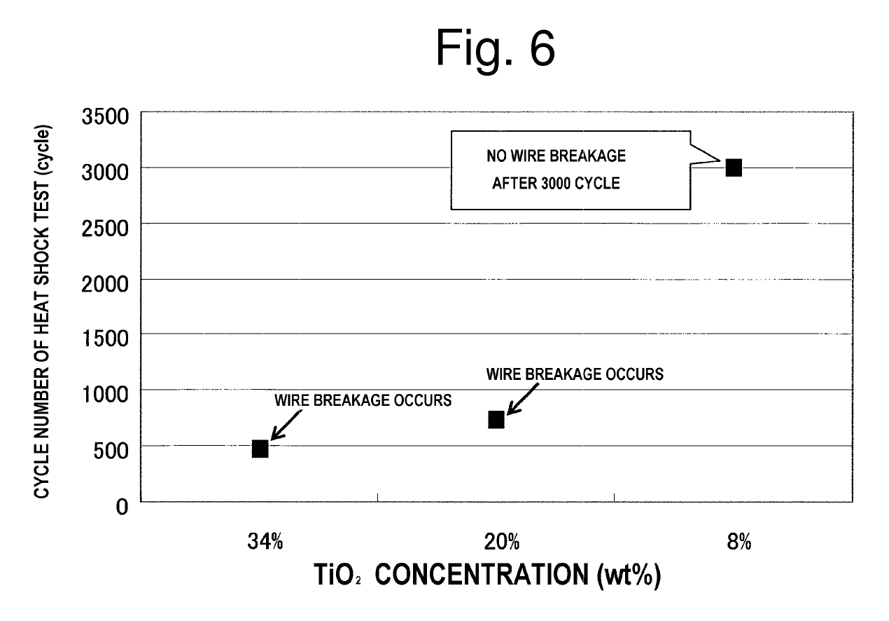

FIG. 6 is a graph showing the measurement of the number of cycles till the bonding wires (Au wires) are broken when the titanium oxide concentration (wt %) in the sealing member is varied in the semiconductor light emitting device 10 of the present exemplary embodiment. In the graph, the horizontal axis shows the titanium oxide concentration (wt %) in the sealing member, and the longitudinal axis shows the number of cycles. In the test, bonding wires (Au wires) with a diameter of 50 μm were used, and three types of semiconductor light emitting devices having titanium oxide concentrations of 34 wt %, 20 wt % and 8 wt %, respectively, were subjected to heat shock test in which the sample was exposed to −40° C. and 125° C. alternately every three minutes. The hardnesses of the sealing member 17 (filler-containing resin) with the respective titanium oxide concentrations were 42, 33 and 28 as determined by a durometer type A.

As shown in the drawing, when the titanium oxide concentration was 34 wt %, the breakage of bonding wires occurred at 466 cycles. When the titanium oxide concentration was 20 wt %, the breakage of bonding wires occurred at 740 cycles. When the titanium oxide concentration was 8 wt %, the breakage of bonding wires didn't occur, even after 3000 cycles.

Accordingly, the heat-shock resistance can be improved as the titanium oxide concentration decreases. In other words, decreasing the titanium oxide concentration can suppress the wire breakage. In particular, when the titanium oxide concentration is equal to 8 wt % or lower, the heat-shock resistance can be improved and the effect for suppressing the wire breakage can be enhanced.

Based on the results of the total lumen maintenance ratio shown in FIG. 5, when the titanium oxide concentration in the sealing member 17 is in the range of 0.1 to 8.0 wt % in the semiconductor light emitting device 10 of the present exemplary embodiment, sufficient luminous flux can be maintained, meaning the luminance level is sufficiently ensured. Furthermore, the results of the heat shock test reveal that the titanium oxide concentration within the above range can suppress the occurrence of wire breakage.

The semiconductor light emitting device 10 of the present exemplary embodiment can utilize the reflection at the interface of the sealing member 17 to thereby enhance luminance. In view of the results shown in FIG. 4, when taking diffuse reflectance and hardness into consideration, it is considered that the titanium oxide concentration can be substantially 8 wt % such that a same level of reflectance can be kept while the TiO₂ concentration is as low as possible. However, the semiconductor light emitting device 10 of the present exemplary embodiment can be configured to have the sealing member 17 surrounding the wavelength conversion layer 14 at its side face with the sealing member 17 having a certain amount of the reflective filler, or titanium oxide. Accordingly, in the configuration of the presently disclosed subject matter, a high total lumen maintenance ratio can be obtained within the entire titanium oxide concentration range of 0.1 to 8.0 wt %.

Namely, according to the configuration of the semiconductor light emitting device 10 of the present exemplary embodiment, in the higher range of the titanium oxide concentration (high white range), the reflectance may be high, but the transmission/scattering ratio may be low, resulting in increased light confining effect. On the other hand, when the titanium oxide concentration is moderate or relatively low (medium white range or low white range), the light transmission/scattering ratio in the sealing member 17 may be high. This means that the sealing member 17 can have an effect in which the light entering from the side face of the wavelength conversion layer 14 can be scattered and directed outside of the member 17. Accordingly, even when the titanium oxide concentration is 8 wt % or less (where the diffuse reflectance may be lowered), the amount of luminous flux can be maintained by the effects of the resulting reflectance and transmission/scattering ratio. In this case, there may be a titanium oxide concentration range around 1 wt % (0.5 to 2.0 wt %) where the total lumen maintenance ratio may be maximum. The reason why the particular high luminance can be maintained within this range is considered to be because the reflectance and the transmission/scattering ratio of the sealing member are well balanced.

As described above, in the semiconductor light emitting device 10 of the present exemplary embodiment, when the filler concentration (titanium oxide concentration) with respect to the base resin (binder) is set to 0.1 to 8 wt %, the resulting semiconductor light emitting device can maintain a high amount of luminous flux with high quality and reliability while suppressing the occurrence of wire breakage. In one mode, the hardness of the sealing member 17 can be 30 or less. In particular, since the titanium oxide concentration is around 1 wt % (0.5 to 2.0 wt %) where the total lumen maintenance ratio may be maximum, this embodiment can suppress the occurrence of wire breakage and enhance the lumen maintenance ratio.

In the semiconductor light emitting device 10 of the present exemplary embodiment, the wavelength conversion layer 14 is disposed on the submount 15 to surround the semiconductor light emitting element 13. The bonding wires 16 can be bonded outside the area where the wavelength conversion layer 14 is formed on the submount 15. This configuration can facilitate the miniaturization of the device serving as a light source, and furthermore, can achieve the miniaturization of the entire optical system for use in small sized optical apparatuses such as vehicle lighting apparatuses including optically designed components such as a lens, a reflector, and other optical components in addition to the present semiconductor light emitting device.

When the semiconductor light emitting element 13 is electrically connected to the submount 15, the chromaticity and the luminance of the semiconductor light emitting element 13 can be measured by bringing a detector such as a probe or the like (not shown) into close contact with the submount 15. Namely, the examination for the optical characteristics can be achieved between process S105 and process S106 so that any substandard article can be discovered at an early stage, thereby decreasing the total production cost during manufacture.

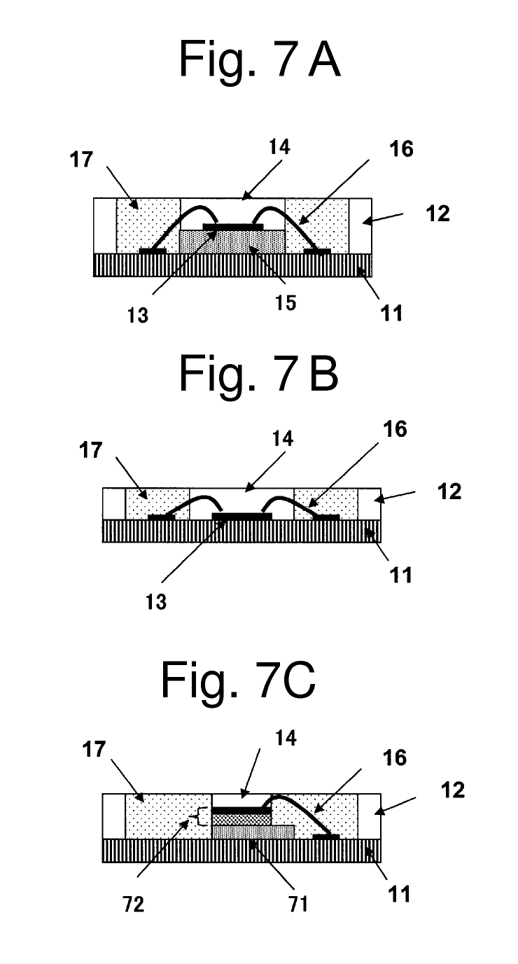

The above exemplary embodiment was described with reference to the semiconductor light emitting device 10 shown in FIG. 1 where the semiconductor light emitting element 13 is connected to the substrate 11 via the submount 15 with the semiconductor light emitting element 13 being a face-down type flip chip element covered with the wavelength conversion layer 14 at its side and upper faces. However, the configuration of the semiconductor light emitting device 10 is not limited to this specific exemplary embodiment. The presently disclosed subject matter can be applied to any configuration where the sealing member 17 can seal at least a portion of the element and/or the wavelength conversion layer surrounding the element, and the bonding wires. It should be noted that such other configurations can be appropriately selected, such as using the structure of the semiconductor light emitting element with or without certain features, such as the submount, the number of bonding wires, electrode patterns, the way to dispose the bonding wire, and the like. For example, FIG. 7A shows another exemplary embodiment where the light emitting layer of the semiconductor light emitting element 13 faces upward, and FIG. 7B shows still another exemplary embodiment where the element 13 is directly mounted on the substrate 11 without a submount. FIG. 7C shows still another exemplary embodiment where a semiconductor light emitting element 72 is fabricated by stacking a light emission layer on an opaque substrate, and the element 72 is mounted on a ceramic substrate 71 so that the light emitting layer faces upward. It should be noted that, when an opaque substrate as shown in FIG. 7C is used, the wavelength conversion layer 14 may not be disposed at the side face of the semiconductor light emitting element.

### Another Exemplary Embodiment

Next, a description will be given of still another exemplary embodiment. In this exemplary embodiment, a method for producing a semiconductor light emitting device 10 according to the first exemplary embodiment with suppressed chromaticity variation and increased process yield will be described. The exemplary embodiment can take advantage of the property in which the chromaticity of the device can be changed in proportion to the logarithm of the titanium oxide concentration in the sealing member 17, thereby improving the chromaticity variation between the products and the process yield.

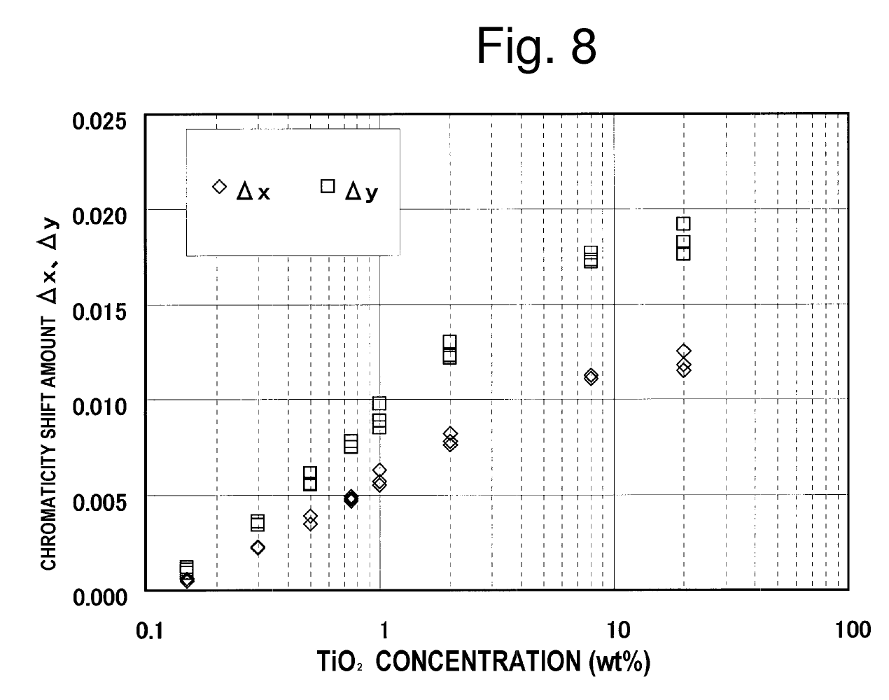

FIG. 8 is a graph showing the chromaticity shift amount distribution for the semiconductor light emitting device 10 when the filler concentration (titanium oxide concentration) in the sealing member 17 is changed. As shown in FIG. 8, the semiconductor light emitting device 10 of the exemplary embodiment can emit light with varied chromaticity after sealing in proportion to the logarithm of the titanium oxide concentration.

In the exemplary embodiment, the semiconductor light emitting device 10 can be produced utilizing this particular property. The basic production method for the semiconductor light emitting device 10 of the exemplary embodiment is the same as that for the first exemplary embodiment except that an additional process feature is involved where the chromaticities of several incomplete semiconductor light emitting devices 10 are measured, and before filling with the sealing member 17, the filler concentration in the sealing member 17 is determined based on the difference between the measured chromaticity and a target chromaticity.

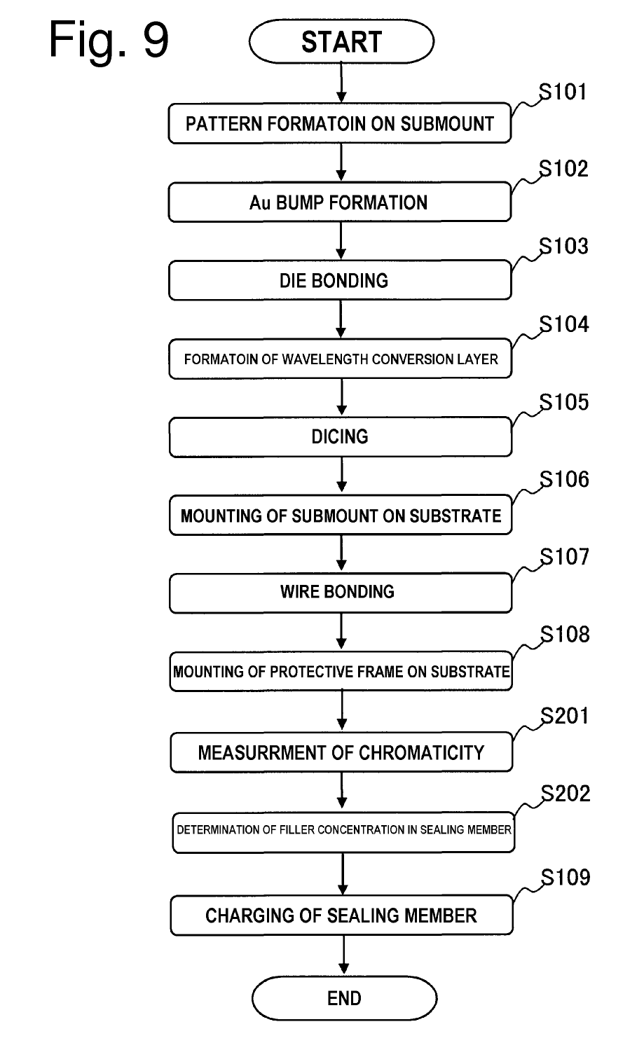

FIG. 9 is a flow chart showing the method for producing the semiconductor light emitting device 10 of the exemplary embodiment.

As shown in FIG. 9, the process can include the same process features as those in the method for producing the device shown in FIG. 2 up to process feature S108. After S108, the prepared semiconductor light emitting elements 13 are measured in chromaticity (at S201), and for each semiconductor light emitting element 13 the filler concentration (titanium oxide concentration) in the sealing member 17 is determined based on a difference between the respective measured chromaticity and the target chromaticity (at S202). Namely, the production method of the exemplary embodiment can include two additional process features as compared to the afore-mentioned production method. Further, in S109, the sealing member containing the reflective filler (titanium oxide) in a determined filler concentration is charged.

In this exemplary embodiment, the titanium oxide concentration in the sealing member 17 can be determined, for example, based on such a graph as shown in FIG. 8, from which the shift amount can be determined as the difference between the measured chromaticity and the target chromaticity.

In an actual production, a plurality of sealing members 17 with various titanium oxide concentrations can be prepared in advance. For example, an average chromaticity for each lot of semiconductor light emitting elements can be calculated in advance, and the respective shift amounts can be determined based on the average chromaticities and the target chromaticity.

Then, an appropriate sealing member 17 having a titanium oxide concentration closest to a titanium oxide concentration that is optimal to the shift amount as determined from the graph of FIG. 8 can be used.

As an exemplary production, several semiconductor light emitting devices were produced by preparing three types of sealing members 17 with their respective titanium oxide concentrations of 0.3 wt %, 1.0 wt % and 8.0 wt % in advance, and utilizing one of the sealing members 17 with the optimal concentration in accordance with the selection scheme as described above. The results in improvement of process yield were determined. Table 1 shows the results.

TABLE 1

| | Titanium oxide conc. | | | |
|---|---|---|---|---|
| Production lot | 0.3 wt % | 1.0 wt % | 8.0 wt % | Application |
| No. 1 | 78.4% | 98.3% | 57.4% | 98.3% |
| No. 2 | 67.0% | 85.2% | 53.4% | 85.2% |
| No. 3 | 63.6% | 85.8% | 50.0% | 85.8% |
| No. 4 | 58.0% | 96.0% | 61.4% | 96.0% |
| No. 5 | 30.7% | 75.0% | 83.5% | 83.5% |
| No. 6 | 27.3% | 73.9% | 83.2% | 83.2% |
| No. 7 | 8.5% | 76.7% | 98.9% | 98.9% |
| No. 8 | 11.9% | 75.0% | 98.9% | 98.9% |
| No. 9 | 2.3% | 51.7% | 100% | 100% |
| Average process yield | 38.6% | 79.7% | 76.3% | 92.2% |

As shown in Table 1, when every production lot utilized a sealing member 17 with a titanium oxide concentration of 0.3 wt %, the average process yield was 38.6%. When every production lot utilized a sealing member 17 with a titanium oxide concentration of 1.0 wt %, the average process yield was 79.7%, and when every production lot utilized a sealing member 17 with a titanium oxide concentration of 8.0 wt %, the average process yield was 76.3%.

On the other hand, when the production method of the present exemplary embodiment is applied, the respective sealing members 17 with optical titanium oxide concentrations were used for the respective production lots as determined in accordance with the above selection scheme. Namely, a sealing member 17 with the titanium oxide concentration of 1.0 wt % was used for the production lots Nos. 1 to 4, and a sealing member 17 with the titanium oxide concentration of 8.0 wt % was used for the production lots Nos. 5 to 9. In this case, the average process yield was improved to 92.2%.

At least one of the reasons why the chromaticity can be shifted in accordance with the reflectance or the titanium oxide concentration can be described as follows. As described above with reference to the FIG. 3, in the semiconductor light emitting device 10, almost all the light emitted from the side face of the semiconductor light emitting element 13 can be reflected from the interface of the sealing member 17 to be returned to the inside of the wavelength conversion layer 14 and directed upward. Accordingly, the amount of light for exciting the wavelength conversion material can be varied in accordance with the reflectance of the seaming member 17, resulting in the varied amount of wavelength converted light. Since the wavelength converted light has a different chromaticity from that of direct light emitted from the semiconductor light emitting element 13, the shift amount of chromaticity can thereby vary.

As described above, in this exemplary embodiment, in addition to the advantageous effects of the first exemplary embodiment, the variation in chromaticity can be suppressed, resulting in an improved process yield.

In this exemplary embodiment, the chromaticity measurement process S201 and the filler concentration determination process S202 can be carried out after the protective frame 12 is fixed in during process S108 and before the sealing member 17 is charged in process S109. However, the chromaticity measurement process S201 and the filler concentration determination process S202 are not limited to this timing in the process. For example, processes S201 and S202 can be carried out between the dicing process S105 and the mounting process S106 or between the mounting process S106 and the wire bonding process S107. In this case, since the semiconductor light emitting element 13 can be electrically connected to the submount 15, the chromaticity and the luminance of the semiconductor light emitting element 13 can be measured by bringing a detector such as a probe or the like into close contact with the submount 15. Alternatively, the processes S201 and S202 can be carried out between the wire bonding process S107 and the mounting process S108.

It will be apparent to those skilled in the art that various modifications and variations can be made in the presently disclosed subject matter without departing from the spirit or scope of the presently disclosed subject matter. Thus, it is intended that the presently disclosed subject matter cover the modifications and variations of the presently disclosed subject matter provided they come within the scope of the appended claims and their equivalents. All related art references described above are hereby incorporated in their entirety by reference.

What is claimed is:

1. A semiconductor light emitting device, comprising:
a semiconductor light emitting element;
a wavelength conversion layer including a wavelength conversion material in a predetermined concentration, the wavelength conversion layer configured to wavelength convert light emitted from the semiconductor light emitting element by exciting the wavelength conversion material with a portion of the light, the wavelength conversion layer having a side face;
a substrate adjacent which the semiconductor light emitting element and the wavelength conversion layer are disposed;
a bonding wire electrically connected with the semiconductor light emitting element; and
a sealing member including a light transmitting resin and titanium dioxide, the sealing member being disposed on the side face of the wavelength conversion layer, the sealing member including the titanium oxide in an amount of 0.1 to 8.0 wt %.

2. The semiconductor light emitting device according to claim 1, wherein the sealing member includes titanium oxide in an amount of 0.5 to 2.0 wt %.

3. The semiconductor light emitting device according to claim 2, wherein the bonding wire is disposed within the sealing member.

4. The semiconductor light emitting device according to claim 1, wherein the bonding wire is disposed within the sealing member.

5. A method for producing a semiconductor light emitting device including a semiconductor light emitting element; a wavelength conversion layer including a wavelength conversion material in a predetermined concentration, the wavelength conversion layer configured to wavelength convert light emitted from the semiconductor light emitting element by exciting the wavelength conversion material with a portion of the light; a substrate adjacent which the semiconductor light emitting element and the wavelength conversion layer are disposed; a bonding wire electrically connected with the semiconductor light emitting element; and a sealing member including a light transmitting resin and titanium oxide, the method for producing comprising:
measuring a chromaticity of light emitted from the semiconductor light emitting element provided with the wavelength conversion layer;
determining a concentration of titanium oxide to be contained in the sealing member based on a chromaticity shift amount, the chromaticity shift amount being a difference between the measured chromaticity and a target chromaticity; and
filling the device with the sealing member including the titanium oxide in the determined concentration of titanium oxide.

6. The method for producing a semiconductor light emitting device according to claim 5, wherein the determining a concentration of titanium oxide includes determining the concentration of titanium oxide based on a predetermined relationship between the chromaticity shift amount and the concentration of titanium oxide.

7. The semiconductor light emitting device according to claim 5, wherein providing a semiconductor light emitting device includes,
locating the semiconductor light emitting element and the wavelength conversion layer on and in direct contact with the substrate,
electrically connecting the bonding wire with the semiconductor light emitting element and the substrate, and
providing the light transmitting resin and titanium dioxide as main ingredients of the sealing member.

8. The semiconductor light emitting device according to claim 1, wherein the semiconductor light emitting element and the wavelength conversion layer are disposed on and in direct contact with the substrate.

9. The semiconductor light emitting device according to claim 1, wherein the bonding wire is electrically connected with the semiconductor light emitting element and the substrate.

10. The semiconductor light emitting device according to claim 1, wherein the light transmitting resin and titanium dioxide are main ingredients of the sealing member.

11. The semiconductor light emitting device according to claim 1, wherein the semiconductor light emitting element is a flip chip type light emitting element.

12. The semiconductor light emitting device according to claim 1, wherein a first end of the bonding wire is attached to a top surface of the semiconductor light emitting element, and an opposite end of the bonding wire is attached to the substrate, and the top surface of the semiconductor light emitting element faces in a light emitting direction of the semiconductor light emitting device.

13. The semiconductor light emitting device according to claim 1, further comprising:
a submount located between the semiconductor light emitting element and the substrate, wherein the bonding wire is attached to a top surface of the submount and extends away from the semiconductor light emitting element and through the sealing member to the substrate such that the bonding wire is completely contained within the sealing member.

14. The semiconductor light emitting device according to claim 1, wherein the bonding wire intersects the side face of the wavelength conversion layer and extends within both the wavelength conversion layer and the sealing member.

15. The semiconductor light emitting device according to claim 1, wherein the semiconductor light emitting element includes a light emission layer located on an opaque substrate, and the light emitting element is mounted on a ceramic substrate.

16. A semiconductor light emitting device having a light emitting axis about which light is emitted in a light emitting direction when power is provided to the semiconductor light emitting device, comprising:
a semiconductor light emitting element;
a wavelength conversion layer including a wavelength conversion material in a predetermined concentration, the wavelength conversion layer configured to wavelength convert light emitted from the semiconductor light emitting element, the wavelength conversion layer having a front face and a side face configured at an angle with respect to the front face, the light emitting axis intersecting the front face and being completely spaced from the side face;
a substrate located adjacent the semiconductor light emitting element and the wavelength conversion layer;
a bonding wire electrically connected with the semiconductor light emitting element; and
a sealing member including a light transmitting resin and a light dispersing material, the sealing member being in contact with the side face of the wavelength conversion layer to form a contact surface, an entire extent of the contact surface being spaced from the light emitting axis.

17. The semiconductor light emitting device according to claim 16, wherein the light dispersing material includes titanium oxide in an amount of 0.1 to 8.0 wt % with respect to the sealing member.

18. The semiconductor light emitting device according to claim 16, wherein the sealing member and the wavelength conversion layer have substantially the same thermal expansion coefficient.

19. The semiconductor light emitting device according to claim 16, wherein the bonding wire is completely contained within the sealing member.

20. The semiconductor light emitting device according to claim 16 wherein the bonding wire intersects the side face of the wavelength conversion layer and extends within both the wavelength conversion layer and the sealing member.
